(19) United States
(12) Patent Application Publication
(10) Pub. No.: US 2025/0393392 A1
(43) Pub. Date: Dec. 25, 2025

(54) LIGHT-EMITTING ELEMENT AND METHOD FOR MANUFACTURING SAME

(71) Applicant: Sharp Display Technology Corporation, Kameyama City, Mie (JP)

(72) Inventor: Yuma YAGUCHI, Sakai City, Osaka (JP)

(21) Appl. No.: 18/881,248

(22) PCT Filed: Aug. 9, 2022
(86) PCT No.: PCT/JP2022/030371

§ 371 Date: Jan. 3, 2025

(51) Int. Cl. H10K 50/84; H10K 50/115; H10K 71/10; H10K 85/60; H10K 102/00

(52) U.S. Cl. CPC H10K 50/846; H10K 50/115; H10K 71/10; H10K 85/6572; H10K 2102/351

(57) ABSTRACT

A light-emitting element includes: an anode and a cathode; and at least one functional layer provided between the anode and the cathode, and containing a ¹O₂ scavenger to serve as an aprotic singlet oxygen scavenger.

### TECHNICAL FIELD

The present disclosure relates to a light-emitting element and a method for manufacturing the light-emitting element.

### BACKGROUND ART

A light-emitting element referred to as a quantum-dot light-emitting diode (QLED) includes a light-emitting layer formed of quantum dots as a light-emitting material.

It is known that the quantum dots are degraded by oxygen. The light-emitting element contains such oxygen as atmospheric oxygen entering the light-emitting element, oxygen included in a solvent and left in the light-emitting element, and oxygen included in a material.

In the presence of a photosensitizer, oxygen in a ground state (triplet oxygen) is irradiated with excitation light such as ultraviolet light. Then, the triplet oxygen is excited, and singlet oxygen is generated. The quantum dots function as the photosensitizer. Many photosensitizers are compounds that are converted from the ground state to a singlet excited state when absorbing light. After that, the photosensitizers quickly undergo intersystem crossing to transit to a triplet excited state. The singlet oxygen oxidizes the quantum dots.

The quantum dots are also referred to as semiconductor nanoparticles because a typical composition of the quantum dots is derived from a semiconductor material. Patent Document 1 discloses a technique to coordinate antioxidant ligands to a surface of semiconductor nanoparticles so as to remove singlet oxygen and reduce degradation of the semiconductor nanoparticles.

### CITATION LIST

### Patent Literature

[Patent Document 1] Japanese Unexamined Patent Application Publication No. 2017-025220

### SUMMARY

### Technical Problem

However, when the antioxidant ligands are coordinated to quantum dots, for example, the quantum dots change in dispersibility. The problem is, when the quantum dots are used for a light-emitting element, the light-emitting element inevitably suffers reduction in light emission characteristics and reliability.

An aspect of the present disclosure sets out to provide a light-emitting element that reduces degradation of quantum dots by singlet oxygen, and that exhibits high emission efficiency and reliability. The aspect also sets out to provide a method for manufacturing the light-emitting element.

### Solution to Problem

In order to solve the above problem, a light-emitting element according to an aspect of the present disclosure includes: a first electrode and a second electrode; and at least one functional layer provided between the first electrode and the second electrode, and containing an aprotic singlet oxygen scavenger.

In order to solve the above problem, a light-emitting element according to an aspect of the present disclosure includes: a first electrode and a second electrode; and at least one functional layer provided between the first electrode and the second electrode, and containing at least one compound selected from the group consisting of: a tertiary amine; carotenoid; an ethylenic compound; naphthalene and a derivative of naphthalene; and anthracene and a derivative of anthracene.

In order to solve the above problems, a method for manufacturing a light-emitting element, which includes: a first electrode and a second electrode; and at least one functional layer provided between the first electrode and the second electrode, includes a functional layer forming step of forming the at least one functional layer. The functional layer forming step involves forming, as the at least one functional layer, a functional layer containing an aprotic singlet oxygen scavenger.

In order to solve the above problems, a method for manufacturing a light-emitting element, which includes: a first electrode and a second electrode; and at least one functional layer provided between the first electrode and the second electrode, includes a functional layer forming step of forming the at least one functional layer. The functional layer forming step involves forming at least one functional layer containing at least one compound selected from the group consisting of: a tertiary amine; carotenoid; an ethylenic compound; naphthalene and a derivative of naphthalene; and anthracene and a derivative of anthracene.

### Advantageous Effects of Invention

An aspect of the present disclosure can provide a light-emitting element that reduces degradation of quantum dots by singlet oxygen, and that exhibits high emission efficiency and reliability. The aspect can also provide a method for manufacturing the light-emitting element.

### BRIEF DESCRIPTION OF DRAWINGS

FIG. 1 is a cross-sectional view schematically illustrating an example of a light-emitting element according to a first embodiment.

FIG. 2 is a flowchart showing a method for manufacturing the light-emitting element illustrated in FIG. 1.

FIG. 3 is a cross-sectional view schematically illustrating an example of a light-emitting element according to a second embodiment.

FIG. 4 is a flowchart showing a method for manufacturing the light-emitting element illustrated in FIG. 3.

FIG. 5 is a cross-sectional view schematically illustrating an example of a light-emitting element according to a third embodiment.

FIG. 6 is a flowchart showing a method for manufacturing the light-emitting element illustrated in FIG. 5.

FIG. 7 is a cross-sectional view schematically illustrating an example of a light-emitting element according to a first modification of the third embodiment.

FIG. 8 is a cross-sectional view schematically illustrating an example of a light-emitting element according to a second modification of the third embodiment.

FIG. 9 is a cross-sectional view schematically illustrating an example of a light-emitting element according to a fourth embodiment.

### DESCRIPTION OF EMBODIMENTS

An embodiment of the present disclosure will be described below in detail. Hereinafter, the term “below” means that a layer is formed in a previous process before a comparative layer, and the term “above” means that a layer is formed in a successive process after a comparative layer. In the description below, the statement “A to B” as to two numbers A and B means “A or more and B or less” unless otherwise specified. Furthermore, in the present disclosure, a composition represented by a chemical formula is preferably stoichiometry. However, the present disclosure shall not exclude a case where the chemical formula is other than stoichiometry.

Moreover, hereinafter, for convenience in description, like reference signs designate members having identical functions throughout the embodiments. These members will not be elaborated upon repeatedly. A second embodiment and the subsequent embodiments to be described later will describe differences from the previously described embodiment and embodiments. As a matter of course, unless otherwise described, the second embodiment and the subsequent embodiments can be modified in the same manner as the previously described embodiment and embodiments.

A light-emitting element according to an aspect of the present disclosure includes: a first electrode; a second electrode; and at least one functional layer provided between the first electrode and the second electrode. Note that, in the present disclosure, layers between the first electrode and the second electrode are collectively referred to as a functional layer.

The functional layer may be either a single layer formed of the light-emitting layer alone, or two or more layers including the light-emitting layer and a functional layer other than the light-emitting layer.

The above light-emitting element is a light-emitting element referred to either as a nano light-emitting diode (LED) or as a quantum-dot light-emitting diode (QLED). The light-emitting layer of the light-emitting element is a quantum-dot light-emitting layer containing quantum dots as a light-emitting material. Hence, the light-emitting element includes, as the functional layer, either: the quantum-dot light-emitting layer; or the quantum-dot light-emitting layer and a first functional layer other than the quantum-dot light-emitting layer.

Note that one of the first electrode or the second electrode is an anode, and another one is a cathode. The above light-emitting element may have a known structure in which the lower electrode serves as the anode and the upper electrode serves as the cathode. Alternatively, the light-emitting element may have an inverted structure in which the lower electrode serves as the cathode and the upper electrode serves as the anode.

The light-emitting element may include at least one functional layer provided between the first electrode and the second electrode, and containing an aprotic singlet oxygen scavenger. The functional layer containing the aprotic singlet oxygen scavenger may be either the light-emitting layer or the first functional layer. For example, in the light-emitting element, at least one of the light-emitting layer or the first functional layer included in the at least one functional layer contains the aprotic singlet oxygen scavenger.

Hence, a method for manufacturing the light-emitting element is a method for manufacturing a light-emitting element including: a first electrode; a second electrode; and at least one functional layer between the first electrode and the second electrode. The method includes a functional layer forming step of forming the at least one functional layer. Thus, the functional layer forming step involves forming, as the functional layer, a functional layer containing an aprotic singlet oxygen scavenger. For example, the functional layer forming step involves forming at least one of the light-emitting layer containing the aprotic singlet oxygen scavenger or the first functional layer containing the aprotic singlet oxygen scavenger.

According to an aspect of the present disclosure, the functional layer is at least one functional layer containing an aprotic singlet oxygen scavenger. Such a feature makes it possible to reduce degradation of quantum dots by singlet oxygen, and to provide the light-emitting element with high emission efficiency and reliability. For example, at least one of the light-emitting layer or the first functional layer contained in the at least one functional layer contains an aprotic singlet oxygen scavenger. Such a feature makes it possible to reduce degradation of quantum dots by singlet oxygen, and to provide the light-emitting element with high emission efficiency and reliability.

Hereinafter, the light-emitting layer would be referred to as an “EML”, and the quantum dots as “QDs”. Furthermore, among the functional layers, a functional layer other than the EML is referred to as a “first functional layer”. Moreover, singlet oxygen is represented as “¹O₂”, and a singlet oxygen scavenger is referred to as a “¹O₂ scavenger”.

### First Embodiment

Described below in detail will be the light-emitting element, showing as an example a case where the EML contains the ¹O₂ scavenger.

### Schematic Configuration of Light-Emitting Element

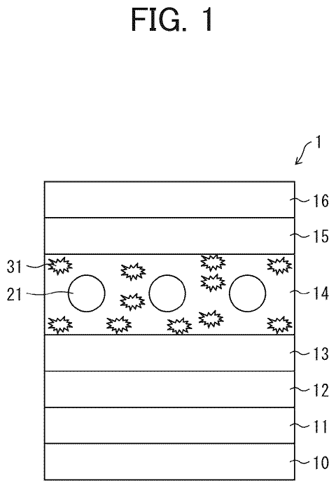

FIG. 1 is a cross-sectional view schematically illustrating an example of a light-emitting element 1 according to this embodiment.

Note that, hereinafter, an electron transport layer is referred to as an “ETL”, a hole transport layer as an “HTL”, and a hole injection layer as an “HIL”.

The light-emitting element 1 illustrated in FIG. 1 includes: an anode 11; an HIL 12; an HTL 13; an EML 14; an ETL 15; and a cathode 16, all of which are sequentially arranged from below.

Note that FIG. 1 illustrates an exemplary case where the light-emitting element 1 has a known structure in which the anode 11 is a lower electrode and the cathode 16 is an upper electrode. However, this embodiment shall not be limited to such a case. As described above, the light-emitting element 1 may have an inverted structure in which the cathode 16 is a lower electrode, and the anode 11 is an upper electrode. In this case, the functional layers are stacked in the reverse order of the functional layers in FIG. 1. That is, the light-emitting element 1 may include: the cathode 16; the ETL 15; the EML 14; the HTL 13; the HIL 12; and the anode 11, all of which are sequentially stacked on top of another from below.

In FIG. 1, the anode 11 is formed on a substrate 10. The substrate 10 functions as a support body that supports all of the layers including the anode 11 to the cathode 16. Hence, the light-emitting element 1 may include the substrate 10 serving as a support body.

The substrate 10 may be, for example, a rigid inorganic substrate such as a glass substrate. Alternatively, the substrate 10 may be a flexible substrate mainly formed of such a resin as polyimide. Note that the substrate 10 may be provided with, for example, a not-shown thin-film transistor (TFT) and a capacitive element.

The anode 11 is an electrode that receives a voltage to supply holes to the EML 14. The cathode 16 is an electrode that receives a voltage to supply electrons to the EML 14. Each of the anode 11 and the cathode 16 contains a conductive material and connects to a not-shown power supply, so that a voltage is applied between the anode 11 and the cathode 16.

At least one of the anode 11 or the cathode 16 is a light-transparent electrode. Note that either the anode 11 or the cathode 16 may be reflective to light; that is, a reflective electrode. The light-emitting element 1 can release light from toward a light-transparent electrode.

If the light-emitting element 1 is a top-emission light-emitting element that emits light from toward the upper electrode, the upper electrode is a light-transparent electrode, and the lower electrode is a reflective electrode. Whereas, if the light-emitting element 1 is a bottom-emission light-emitting element that emits light from toward the lower electrode, the lower electrode is a light-transparent electrode, and the lower electrode is a reflective electrode.

The light-transparent electrode is formed of a conductive light-transparent material such as, for example, indium tin oxide (ITO) or indium zinc oxide (IZO).

Whereas, the reflective electrode is formed of, for example, a conductive light-reflective material including a metal such as aluminum (Al) or silver (Ag), or including an alloy containing these metals. Note that a layer made of the light-transparent material and a layer made of the light-reflective material may be stacked on top of another to form the reflective electrode.

The HIL 12 is a charge injection layer containing, as a functional material, an HIL material (a hole-transporting material) capable of transporting the holes. The HIL 12 has a hole injection function to enhance efficiency in injecting the holes from the anode 11 into the HTL 13. Examples of the HIL material include a composite (PEDOT:PSS) containing poly(3,4-ethylenedioxythiophene) (PEDOT) and polystyrene sulphonate (PSS).

The HTL 13 is a charge transport layer containing, as a functional material, an HTL material (a hole-transporting material) capable of transporting the holes. The HTL 13 has a hole-transporting function to enhance efficiency in transporting the holes to the EML 14. The HTL material may be, for example, an organic hole-transporting material, such as poly[(9,9-dioctylfluorenyl-2,7-diyl)-co-(4,4′-(N-(4-sec-butylphenyl))diphenylamine)] (TFB), poly(4- butyltriphenylamine) (p-TPD), poly(9-vinylcarbazole) (PVK), [9,9′-[1,2-phenylenebis (methylene)]bis[N3,N3,N6,N6-tetrakis (4-methoxyphenyl)-9H-carbazole-3,6-diamine] (V886), or 7,7′-bi [1,4] benzoxazino[2,3,4-kl]phenoxazine (HN-D1). Alternatively, the HTL material may be, for example, an inorganic hole-transporting material such as nanoparticles of p-type oxide semiconductors such as nickel oxide (NiO). Among these HTL materials, the nanoparticles of a p-type oxide semiconductor are preferable because the nanoparticles are chemically highly stable. Particularly preferable are NiO nanoparticles in view of capability in transporting holes and energy level.

Note that, in the present disclosure, the term “nanoparticles” refers to dots (particles) formed of particles having a maximum width of less than 1000 nm. A nanoparticle may have any given shape as long as the maximum width of the nanoparticle is within the above range. The shape of the nanoparticle shall not be limited to a spherical shape (a circular cross-section). For example, the nanoparticle may have a polygonal cross-section, a bar-like three dimensional shape, a branch-like three dimensional shape, or a three dimensional shape having asperities on the surface. Alternatively, the nanoparticle may have a combination of those shapes.

The ETL 15 is a charge transport layer containing, as a functional material, an ETL material (an electron-transporting material) capable of transporting the electrons. The ETL 15 has an electron-transporting function to enhance efficiency in transporting the electrons to the EML 14. Examples of the ETL material include: nanoparticles of an n-type oxide semiconductor; and nanoparticles of an organometallic complex. Examples of the n-type oxide semiconductor include n-type metal oxides such as zinc oxide (ZnO) and zinc magnesium oxide (ZnMgO). Examples of the organometallic complex include tris (8-quinolinol) aluminum complex (Alq3). Furthermore, the ETL material may also be an organic material such as (2,2′,2″-(1,3,5-benzinetriyl)-tris(1-phenyl-1-H-benzimidazole) (TPBi) or bathocuproine (BCP).

In particular, adsorption of oxygen to an n-type oxide semiconductor is defective adsorption that creates a depletion layer on a surface of the oxide semiconductor. Hence, when nanoparticles of an n-type oxide semiconductor such as ZnO or ZnMgO adsorb a large amount of oxygen, the oxygen traps the electrons so as to successfully change the ETL in characteristic. Specifically, the adsorbed oxygen consumes some of the electrons flowing in the oxide semiconductor nanoparticles and reduces the amount of the electron supply. Hence, if a carrier balance in the light-emitting element 1 shows an excess of electrons, the adsorbed oxygen can reduce the injection of the electrons into the EML 14 and adjust the carrier balance. Thus, the n-type oxide semiconductor nanoparticles used as the ETL material improve light emission characteristics and enhances external quantum efficiency (EQE). Hence, as the ETL material, the n-type oxide semiconductor nanoparticles are preferable. Among the nanoparticles, the ETL material preferably contains at least the ZnO nanoparticles or the ZnMgO nanoparticles because such nanoparticles are chemically highly stable. Particularly preferable are ZnMgO nanoparticles in view of capability in transporting electrons and energy level.

The EML 14 contains a light-emitting material as a functional material, and the light-emitting material is nano-sized QDs 21 in accordance with a color of light to be emitted. The EML 14 emits light by recombination of the holes transported from the anode 11 and the electrons transported from the cathode 16.

Each of the QDs 21 is a dot made of a nanoparticle having a maximum width of 100 nm or less. As described before, the QD is also referred to as a semiconductor nanoparticle because a typical composition of the QD is derived from a semiconductor material. Moreover, the QD is also referred to as a nanocrystal because the QD has a specific crystal structure.

Each of the QDs 21 may have any given shape as long as the maximum width of the QD 21 is within the above range. The shape of the QD 21 shall not be limited to a three-dimensional spherical shape (a circular cross-section). For example, the nanoparticle may have a polygonal cross-section, a bar-like three dimensional shape, a branch-like three dimensional shape, or a three dimensional shape having asperities on the surface. Alternatively, the nanoparticle may have a combination of those shapes.

Each of the QDs 21 may be a core QD. Alternatively, each of the QDs 21 may be either a core-shell QD containing a core and a shell, or a core-multishell QD containing a core and shells. If the QD 21 contains a shell, the QD 21 may have a core in the center, and the shell may be provided to a surface of the core. The shell desirably covers the entire core; however, the shell does not have to completely cover the core. Furthermore, the QD 21 may be a binary-core QD, a tertiary-core QD, or a quaternary-core QD. Note that the QDs 21 may contain doped nanoparticles, or may have a composition-gradient structure.

The core may be formed of, for example, Si, Ge, CdSe, CdS, CdTe, InP, GaP, InN, ZnSe, ZnS, ZnTe, CdSeTe, GalnP, or ZnSeTe. The shell may be formed of, for example, CdS, ZnS, CdSSe, CdTeSe, CdSTe, ZnSSe, ZnSTe, ZnTeSe, or AIP.

An emission wavelength of the QD 21 can be varied in various manners depending on, for example, the size and the composition of the particle. The QD 21 emits visible light. A particle size and a composition of the QD 21 are appropriately adjusted so that the emitted light can be colored red, green or blue.

QDs are commercially available. Such QDs are typically provided in the form of a quantum-dot-dispersed solution containing organic ligands. Note that, hereinafter, a quantum-dot-dispersed liquid containing quantum dots (QDs) may be referred to as a “QD-dispersed liquid” regardless of whether or not the organic ligands are contained. Furthermore, the QDs can be synthesized by any given technique. The QDs are synthesized by, for example, a wet technique. The organic ligands are coordinated to a surface of the QDs to control a particle size of the QDs. The organic ligands are used as a dispersant to improve dispersibility of the QDs in the QD-dispersed liquid. The organic ligands are also used to improve surface stability and storage stability of the QDs.

Hence, the QDs 21 may be coordinated with the organic ligands. In addition, the QDs 21 may be coordinated with desired organic or inorganic ligands exchanged through, for example, ligand exchange. These ligands shall not be limited to a particular kind of ligands, and may be any given various known ligands.

As described before, the light-emitting element 1 illustrated in FIG. 1 has the EML 14 containing a ¹O₂ scavenger 31 (a singlet oxygen scavenger). Hence, the EML 14 includes: the QDs 21; and the ¹O₂ scavenger 31.

The ¹O₂ scavenger 31 is used not to consume the oxygen in the system but to inactivate the oxygen. The ¹O₂ scavenger 31 deactivates ¹O₂ in an excited state, and brings the excited ¹O₂ back to triplet oxygen (³O₂) in a ground state in a stable condition.

As described before, the ¹O₂ scavenger 31 is an aprotic ¹O₂ scavenger. The aprotic ¹O₂ scavenger is either a ¹O₂ scavenger that does not contain a hetero element such as an oxygen element and a nitrogen element, or a ¹O₂ scavenger that contains a hetero element to which no hydrogen element directly bonds. The aprotic ¹O₂ scavenger 31 is an aprotic ¹O₂ scavenger because of the reasons below.

Unlike the aprotic ¹O₂ scavenger, a protic ¹O₂ scavenger has a structure in which a hydrogen element directly bonds to a hetero element. Regardless of usage, the protic ¹O₂ scavenger coordinates to the QDs 21 immediately when added.

Hence, no matter how small the amount is, the protic ¹O₂ scavenger coordinates to the QDs 21 immediately when added. Note that, depending on the usage of the protic ¹O₂ scavenger, variations are observed of a coordination rate of the protic ¹O₂ scavenger to the ligands previously coordinated to the QDs 21, with respect to QDs 21. A larger amount of the coordinated protic ¹O₂ scavenger is highly likely to cause poorer light emission characteristics and material stability. In particular, the QDs 21 are significantly degraded in dispersibility if the protic ¹O₂ scavenger coordinated to the QDs 21 is formed of bifunctional molecules each containing two or more coordinating functional groups including at least one of a primary amino group or a secondary amino group. As can be seen, if the ¹O₂ scavenger is coordinated to the QDs 21, the QDs 21 changes in, for example, dispersibility. As a result, the light-emitting element 1 inevitably suffers reduction in light emission characteristics and reliability.

However, as described above, the aprotic ¹O₂ scavenger is either a ¹O₂ scavenger that does not contain a hetero element such as an oxygen element and a nitrogen element, or a ¹O₂ scavenger that contains a hetero element to which no hydrogen element directly bonds. The aprotic ¹O₂ scavenger does not have any coordinating functional groups capable of coordinating to the QDs 21. Note that the coordinating functional group is also referred to as a ligand coordinating group.

The coordinating functional group may be at least one selected from the group consisting of: a thiol group; a primary amino group; a secondary amino group; a carboxyl group; a primary phosphonic group; a secondary phosphonic group; a primary phosphine group; a secondary phosphine group; a primary phosphine oxide group; and a secondary phosphine oxide group.

The ¹O₂ scavenger 31 does not have any of these coordinating functional groups, does not react with QDs 21, or does not act as ligands. Hence, the ¹O₂ scavenger 31 neither coordinates to the QDs 21 nor adversely affects dispersibility and light emission characteristics of the QDs 21.

Note that, here, the term “to coordinate” means that the ligands bond to the surface of the QDs 21. Hence, the statement “the ¹O₂ scavenger 31 does not coordinate to the QDs 21” means that the ¹O₂ scavenger 31 does not bond to the surface of the QDs 21.

The ¹O₂ scavenger 31 contained in the functional layer can be identified, using such a technique as, for example, a time-of-flight secondary ion mass spectrometry (TOF-SIMS) to analyze an element and a molecule structure included in each place.

Examples of the ¹O₂ scavenger 31 include: an energy-absorbing aprotic ¹O₂ scavenger (an energy-absorbing aprotic singlet oxygen scavenger); and an oxidizable aprotic ¹O₂ scavenger (an oxidizable aprotic singlet oxygen scavenger).

The energy-absorbing aprotic ¹O₂ scavenger is an aprotic singlet oxygen scavenger that absorbs energy of ¹O₂ and brings the ¹O₂ back to triplet oxygen. Note that, hereinafter, triplet oxygen is referred to as “³O₂”. The energy-absorbing aprotic singlet oxygen scavenger absorbs energy of ¹O₂, and brings the ¹O₂ back to ³O₂, so as to repeatedly eliminate ¹O₂.

The oxidizable aprotic ¹O₂ scavenger is an aprotic ¹O₂ scavenger that is oxidized itself to bring the ¹O₂ back to ³O₂. The oxidizable aprotic ¹O₂ scavenger oxidizes itself to eliminate ¹O₂, thereby functioning as an advance guard against ¹O₂ that causes oxidization of the QDs 21. After oxidized, the oxidizable aprotic ¹O₂ scavenger loses its function.

The ¹O₂ scavenger 31 preferably contains at least one of the energy-absorbing aprotic ¹O₂ scavenger or the oxidizable aprotic ¹O₂ scavenger, and, more preferably, contains the energy-absorbing aprotic ¹O₂ scavenger.

Examples of the ¹O₂ scavenger 31 include at least one compound selected from the group consisting of: a tertiary amine; carotenoid; an ethylenic compound; naphthalene and a derivative of naphthalene; and anthracene and a derivative of anthracene. The light-emitting element 1 preferably contains, as the ¹O₂ scavenger 31, at least one selected from the group consisting of these exemplified ¹O₂ scavengers.

The aprotic ¹O₂ scavenger, which contains a hetero element to which no hydrogen element directly bonds, functions as an energy-absorbing aprotic ¹O₂ scavenger. The aprotic ¹O₂ scavenger, which does not contain a hetero element, is mainly used as an oxidizable aprotic ¹O₂ scavenger. However, the aprotic ¹O₂ scavenger could be used as an energy-absorbing aprotic ¹O₂ scavenger.

Examples of the aprotic ¹O₂ scavenger, which is used as an energy-absorbing aprotic ¹O₂ scavenger containing a hetero element to which no hydrogen element directly bonds, includes: a tertiary amine; an ethylenic compound containing a hetero element; naphthalenes (naphthalene derivatives) containing a hetero element; and anthracenes (anthracene derivatives) containing a hetero element.

The ¹O₂ scavenger 31 is a monomer. The monomer refers to a compound having a molecular weight of 1000 or less. A polymer has a structure as a unit (a monomer) repeating many times. The polymer typically has either approximately 1000 or more atoms, or molecules highly polymerized so that the polymer has a molecular weight of 10000 or more. Furthermore, an oligomer has a structure as a unit (a monomer) repeating not many times. The oligomer typically has a molecular weight of 1000 to 10000.

The ¹O₂ scavenger 31 may contain either an oligomer or a polymer. However, the polymerized or oligomerized ¹O₂ scavenger has larger molecules. Moreover, the polymer is basically highly insulative, and could reduce light emission characteristics. Hence, the ¹O₂ scavenger 31 is preferably a monomer. The ¹O₂ scavenger 31 formed of a monomer can fill the gaps between adjacent QDs 21. Such a feature can efficiently reduce an adverse effect that the ¹O₂ has on the QDs 21, thereby successfully eliminating the ¹O₂.

Hence, a monomer is preferably used as the ¹O₂ scavenger 31 such as a tertiary amine, an ethylenic compound containing a hetero element, naphthalenes (naphthalene derivatives) containing a hetero element, and anthracenes (anthoracene derivatives) containing a hetero element.

Examples of the tertiary amine includes: triethylamine; N,N-dimethylaniline; 1,4-diazabicyclo[2.2.2]octane (DABCO); and 1-ethylimidazole. Examples of the ethylenic compound containing a hetero element include 1,2-diethoxyethene.

Examples of the naphthalenes containing a hetero element include a naphthalene derivative in which either at least one of carbon elements forming a naphthalene ring or at least one of hydrogen elements bonding to the naphthalene ring is substituted with a hetero element, and in which the at least one hydrogen element does not directly bond to the hetero element.

Examples of the anthracenes containing a hetero element include an anthracene derivative in which either at least one of carbon elements forming an anthracene ring or at least one of hydrogen elements bonding to the anthracene ring is substituted with a hetero element, and in which the at least one hydrogen element does not directly bond to the hetero element. Examples of such anthracenes include: dimethoxyanthracene; and 9,10-bis(4-methoxyphenyl) anthracene.

Examples of the aprotic ¹O₂ scavenger, which is used as an oxidizable aprotic ¹O₂ scavenger and contains no hetero naphthalene, include: an ethylenic compound containing no hetero element; naphthalenes (naphthalene and a naphthalene derivative) containing no hetero element; anthracenes (anthracene and an anthracene derivative) containing no hetero element; and 1,2,3,4-tetraphenyl-1,3-cyclopentadiene formed of cyclopentadiene, containing no hetero element, with a phenyl group alone substituted.

Examples of the ethylenic compound containing no hetero element include: tetramethylethylene; and cyclopentene.

Examples of the naphthalenes containing no hetero element include naphthalene in which either at least one of carbon elements forming a naphthalene ring or at least one of hydrogen elements bonding to the naphthalene ring may be substituted with an element other than a hetero element. Examples of such naphthalenes include: naphthalene; and dimethylnaphthalene.

Examples of the anthracenes containing no hetero element include anthracene in which either at least one of carbon elements forming an anthracene ring or at least one of hydrogen elements bonding to the anthracene ring may be substituted with an element other than a hetero element. Examples of the anthracenes includes anthracene.

Note that, as described before, the ¹O₂ scavenger 31 may be carotenoid. The carotenoid is, for example, aprotic carotenoid such as lycopene, a-carotene, and B-carotene. These exemplary carotenoids are aprotic ¹O₂ scavengers containing no hetero element. Depending on conditions, these exemplary carotenoids may be used either as oxidizable aprotic ¹O₂ scavengers or as energy-absorbing aprotic ¹O₂ scavengers because of complex factors.

These aprotic ¹O₂ scavengers to be used as the ¹O₂ scavenger 31 may be either one kind of aprotic ¹O₂ scavenger or two or more kinds of ¹O₂ scavengers mixed together as appropriate. Among these aprotic ¹O₂ scavengers, the ¹O₂ scavenger 31 is preferably a tertiary amine. Among tertiary amines, the ¹O₂ scavenger 31 is more preferably one selected from the group consisting of: 1,4-diazabicyclo[2.2.2] octane; triethylamine; and N,N-dimethylaniline.

Hence, the light-emitting element 1 preferably contains a tertiary amine as the ¹O₂ scavenger 31. Furthermore, the light-emitting element 1 preferably contains, as the tertiary amine, at least one selected from the group consisting of: 1,4-diazabicyclo [2.2.2] octane; triethylamine; and N,N-dimethylaniline.

Note that the ¹O₂ scavenger 31 used in this embodiment shall not be limited to the aprotic ¹O₂ scavengers described above as an example. The ¹O₂ scavenger 31 may be, for example, furans such as furan and a derivative of furan.

In this embodiment, in the EML 14, a content ratio of the ¹O₂ scavenger 31 per 1 part by weight of the QDs 21 is preferably within a range of 0.001 parts by weight or more and 1 part by weight or less. In the EML 14, if the content ratio of the ¹O₂ scavenger 31 per 1 part by weight of the QDs 21 exceeds 1 part by weight, the EML 14 might deteriorate in film quality. Furthermore, a decrease in the rate of the QDs 21 contained in the EML 14 could lead to a significant reduction in light emission characteristics. Whereas, in the EML 14, if the content ratio of the ¹O₂ scavenger 31 per 1 part by weight of the QDs 21 is less than 0.001 parts by weight, degradation of the QDs 21 by ¹O₂ might not be sufficiently reduced.

Method for Manufacturing Light-Emitting Element 1. Described below will be a method for manufacturing a light-emitting element according to an aspect of the present disclosure, with reference to a method for manufacturing the light-emitting element 1 illustrated in FIG. 1 as an example.

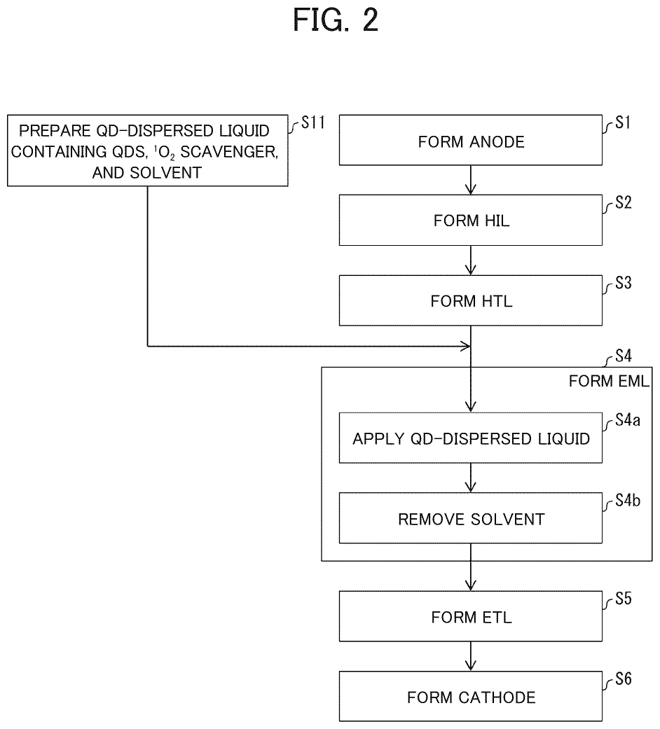

FIG. 2 is a flowchart showing a method for manufacturing the light-emitting element 1 illustrated in FIG. 1.

In the method for manufacturing the light-emitting element 1 illustrated in FIG. 1, as shown in FIG. 2, first, the anode 11 is formed on the substrate 10 (Step S1, an anode forming step). Next, a functional layer forming step is carried out to form a plurality of functional layers above the anode 11. The functional layer forming step according to this embodiment includes Step S2 to Step S5 and Step S11 below.

In this embodiment, after Step S1, first, the HIL12 is formed on the anode 11 as the functional layer forming step (Step S2, an HIL forming step). Next, the HTL 13 is formed (Step S3, an HTL forming step). So far, the method is the same as a method for manufacturing a typical QLED.

On the other hand, a QD-dispersed liquid (a quantum-dot-dispersed liquid) is prepared (manufactured) to contain the QDs 21, the ¹O₂ scavenger 31, and a solvent (Step S11, a QD-dispersed liquid preparing step).

The solvent is, for example, a nonpolar solvent such as hexane. In the QD-dispersed liquid, concentration of the QDs 21 may be any given concentration to be appropriately set according to, for example, a design value of a thickness of the EML 14.

In the QD-dispersed liquid, a content ratio of the ¹O₂ scavenger 31 per 1 part by weight of the QDs 21 is set so that, in the EML 14, the content ratio of the ¹O₂ scavenger 31 per 1 part by weight of the QDs 21 is preferably within a range of 0.001 parts by weight or more and 1 part by weight or less. Hence, in the QD-dispersed liquid, the content ratio of the ¹O₂ scavenger 31 per 1 part by weight of the QDs 21 is set within a range of, for example, 0.001 parts by weight or more and 1 part by weight or less. In the QD-dispersed liquid, if the content ratio of the ¹O₂ scavenger 31 per 1 part by weight of the QDs 21 exceeds 1 part by weight, the EML 14 to be formed might deteriorate in quality. Furthermore, a decrease in the rate of the QDs 21 contained in the EML 14 to be formed could lead to a significant reduction in light emission characteristics. Whereas, in the QD-dispersed liquid, if the content ratio of the ¹O₂ scavenger 31 per 1 part by weight of the QDs 21 is less than 0.001 parts by weight, degradation of the QDs 21 by ¹O₂ might not be sufficiently reduced.

Next, the EML 14 is formed of the QD-dispersed liquid (Step S4, an EML forming step). Note that Step S11 may be carried out before Step S4.

At Step S4, first, the QD-dispersed liquid is applied to the HTL 13 serving as an underlayer of the EML 14 (Step S4a, a QD-dispersed-liquid applying step). Thus, a coat of the QD-dispersed liquid is formed. The QD-dispersed liquid is applied by, for example, spin coating

Next, for example, heat is applied to the coat to remove a solvent contained in the coat (i.e., the applied QD-dispersed liquid), and to dry the coat (Step S4b, a solvent removing step). Hence, the EML 14 containing the QDs 21 and the ¹O₂ scavenger 31 is formed.

Note that the QDs 21 may be coordinated with ligands. The QD-dispersed liquid and the EML 14 may contain known ligands to serve as the ligands.

Next, the ETL 15 is formed (Step S5, an ETL forming step). After that, the cathode 16 is formed (Step S6, a cathode forming step). This is how the light-emitting element 1 illustrated in FIG. 1 is formed.

The method for manufacturing the light-emitting element 1 is the same as a typical method for manufacturing a QLED except that the ¹O₂ scavenger 31 is added to the QD-dispersed liquid. The anode 11 and the cathode 16 can be formed by, for example, vapor deposition, sputtering, or inkjet printing. Furthermore, each of the functional layers included in the light-emitting element 1 can be formed of a coat. Each functional layer can be formed by, for example, spin coating, vacuum evaporation, or inkjet printing.

### Specific Example of Method for Manufacturing Light-Emitting Element 1

Described next will be an example of the method for manufacturing the light-emitting element 1 illustrated in FIG. 1. The light-emitting element 1 illustrated in FIG. 1 is formed of, for example, the anode 11, the HIL 12, the HTL 13, the EML 14, the ETL 15, and the cathode 16 sequentially deposited above the substrate 10.

In this embodiment, as an example, an ITO layer to serve as the anode 11 is formed on the substrate 10. Next, a solution containing PEDOT:PSS is applied to the ITO layer by spin coating. Then, the solution is baked and the solvent is vaporized. Hence, a PEDOT:PSS layer is formed to serve as the HIL 12. Next, a solution containing TFB is applied to the PEDOT:PSS layer by spin coating. Then, the solution is baked and the solvent is vaporized. Hence, a TFB layer is formed as the HTL 13.

On the other hand, QDs serving as the QDs 21 and having a core-shell structure of InP/ZnS with a number-average particle size (diameter) of 10 nm are dispersed in hexane serving as a solvent, so that the QDs have a concentration of 6 mg/mL. Next, the DABCO serving as the ¹O₂ scavenger 31 is added to the obtained QD-dispersed liquid at a rate of 5 mg/mL with respect to the above hexane. Thus, prepared is a QD-dispersed liquid in which 1 mL of hexane contains 5 mg of the DABCO with respect to 6 mg of QDs.

Then, the QD-dispersed liquid is applied to the TFB layer by spin coating at a rotational speed of 200 rpm for 30 seconds. After that, the QD-dispersed liquid is baked at 80° C. for 10 minutes, and the hexane is vaporized. Hence, on the TFB layer, the EML 14 containing the QDs and the DABCO is formed to have a thickness of, for example, 20 nm. Next, a dispersion liquid containing ZnMgO nanoparticles is applied to the EML 14 by spin coating. Then, the dispersion liquid is baked and the solvent is vaporized. Hence, a ZnMgO nanoparticle layer is formed to serve as the ETL 15. Next, on the ZnO nanoparticle layer, an Al layer is formed to serve as the cathode 16.

### Advantageous Effects

As described before, the QDs 21 function as a photosensitizer. When the QDs 21 are excited, energy transfers from QDs 21 to ³O₂ ; that is, oxygen in the ground state. Thus, ¹O₂ is generated, and QDs 21 are oxidized. Hence, in the presence of a photosensitizer, when ³O₂ is irradiated with excitation light, ³O₂ is excited and ¹O₂ is generated. The light-emitting element 1 contains such oxygen as atmospheric oxygen entering therein, oxygen included in a solvent and left in the light-emitting element 1, and oxygen included in a material. When ¹O₂ is repeatedly generated, and the surface of the QDs 21 is repeatedly oxidized, non-light-emitting oxides are generated on the surface of QDs 21 in the form of islands. Such oxides gradually reduce emission intensity of the QDs 21. The generation of ¹O₂ can be confirmed when distinctive phosphorus light (approximately 1270 nm) is observed.

However, according to this embodiment, as described above, the EML 14 contains an aprotic ¹O₂ scavenger serving as the ¹O₂ scavenger 31. Such a feature brings generated ¹O₂ back to ³O₂ and eliminates ¹O₂ without adversely affecting the dispersibility and the light emission characteristics of the QDs 21.

Hence, this embodiment can reduce oxidization, and the resulting degradation, of the QDs 21 without adversely affecting the dispersibility and the light emission characteristics of the QDs 21. As a result, this embodiment can provide the light-emitting element 1 with high light emission efficiency and reliability.

In addition, as seen in the case of the ZnMgO nanoparticles in the ETL 15 described before, the presence of oxygen in the system is advantageous for the light emission characteristics. The ¹O₂ scavenger 31 solely deactivates the excited state of oxygen, and does not remove oxygen. Hence, this embodiment makes it possible to curb reduction in the light emission characteristics of QDs 21 while the QDs 21 and oxide in the system coexist.

Furthermore, in the manufacturing process, the QDs 21 are also oxidized when exposed to the atmosphere or a solvent. For example, a fluorescent lamp also works as excitation light. According to this embodiment, the ¹O₂ scavenger 31 contained in the EML 14 can protect the QDs 21 not only from ¹O₂ generated after formation of the light-emitting element 1, but also from ¹O₂ generated in the manufacturing process.

Furthermore, according to this embodiment, the ¹O₂ scavenger 31 is simply mixed together with the QD-dispersed liquid. As a result, the EML 14 light-emitting layer is successfully formed to contain the ¹O₂ scavenger without changing the process itself. Hence, according to this embodiment, existing facilities can be used as they are. As a result, the above method can be readily introduced.

### Second Embodiment

A light-emitting element according to an aspect of the present disclosure may include the EML 14 and the first functional layer both serving as the at least one functional layer as described in the first embodiment. As to a light-emitting element according to this embodiment, the first functional layer may be adjacent to the EML 14, and may contain an oxygen-element-containing compound. The EML 14 may contain the ¹O₂ scavenger 31. In the EML 14, density of the ¹O₂ scavenger 31 may be higher in a portion closer to the first functional layer with respect to a center of the EML 14 in a thickness direction than in a portion farther away from the first functional layer with respect to the center of the EML 14 in the thickness direction.

Furthermore, in the light-emitting element, the density of the ¹O₂ scavenger 31 in the EML 14 may be higher toward the first functional layer in the thickness direction of the EML 14. Note that, in this case, density distribution of the ¹O₂ scavenger 31 in the EML 14 does not have to increase linearly (i.e., continuously as seen in a linear function). The distribution of the density may increase stepwise. In the present disclosure, the density of the ¹O₂ scavenger 31 in the EML 14 is higher toward the first functional layer. This statement means that the density of the ¹O₂ scavenger 31 in the EML 14 may be higher linearly or stepwise toward the first functional layer in the thickness direction of the EML 14.

Described below will be a case where the first functional layer is a carrier transport layer, together with a case where the light-emitting element has a known structure and where the carrier transport layer serving as the first functional layer is the ETL 15.

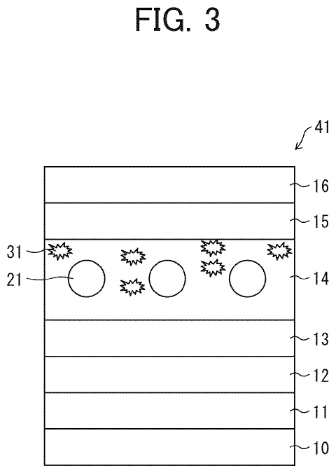

FIG. 3 is a cross-sectional view schematically illustrating an example of a light-emitting element 41 according to this embodiment.

The light-emitting element 41 illustrated in FIG. 3 includes, for example: the anode 11; the HIL 12; the HTL 13; the EML 14; the ETL 15; and the cathode 16, all of which are sequentially arranged from below as seen in the light-emitting element 1 described in the first embodiment. Furthermore, similar to the light-emitting element 1, the ETL 15 contains, as an oxygen-element-containing ETL material (an oxygen-element-containing compound), nanoparticles of, for example, either an n-type metal oxide such as ZnO and ZnMgO or an oxygen-element-containing organometallic complex such as Alq3. The ¹O₂ scavenger 31 is mixed in the EML 14.

Note that, as to the light-emitting element 41 illustrated in FIG. 3, in the EML 14, the density of the ¹O₂ scavenger 31 is higher in a portion closer to the ETL 15 with respect to the center of the EML 14 in the thickness direction than in a portion farther away from the ETL 15 with respect to the center of the EML 14 in the thickness direction. More specifically, the density of the ¹O₂ scavenger 31 in the EML 14 is higher toward the ETL 15. The light-emitting element 41 is different from the light-emitting element 1 in this point.

### Method for Manufacturing Light-Emitting Element 41

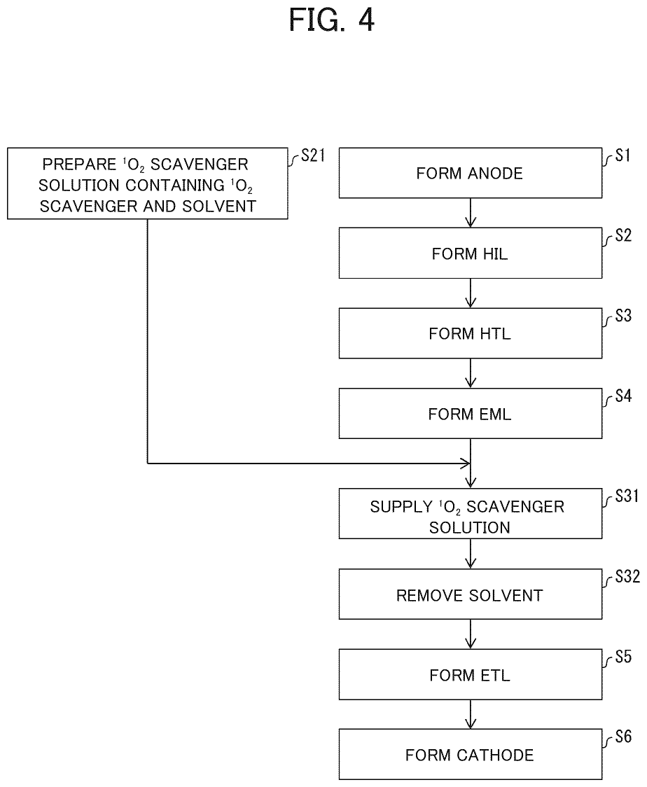

FIG. 4 is a flowchart showing a method for manufacturing the light-emitting element 41 illustrated in FIG. 3.

The method for manufacturing the light-emitting element 41 illustrated in FIG. 3 involves Step S1 (the anode forming step) to Step S3 (the HTL forming step) in FIG. 4, as seen in the method for manufacturing the light-emitting element 1 described before. After that, in this embodiment, the EML 14 containing the QDs 21 is formed of a QD-dispersed liquid containing the QDs 21 and a solvent (Step S4, the EML forming step). The solvent is, for example, a nonpolar solvent such as hexane as seen in the first embodiment. In the QD-dispersed liquid, concentration of the QDs 21 may be any given concentration to be appropriately set according to, for example, a design value of a thickness of the EML 14.

In this embodiment, the QD-dispersed liquid not containing the ¹O₂ scavenger is applied to the HTL 13 so as to form a coat of the QD-dispersed liquid. After that, for example, heat is applied to the coat to remove the solvent contained in the coat. Hence, the EML 14 not containing the ¹O₂ scavenger 31 is once formed. Note that, in this embodiment, the QD-dispersed liquid may be prepared before Step S4. So far, the method is the same as a method for manufacturing a typical QLED.

Whereas, in this embodiment, as illustrated in FIG. 4, a ¹O₂ scavenger solution is prepared (manufactured) to contain the ¹O₂ scavenger 31 and a solvent (Step S21, a ¹O₂ scavenger solution preparing step). The solvent is, for example, an amphoteric solvent such as isopropyl alcohol (IPA) or ethanol. Concentration of the ¹O₂ scavenger 31 in the ¹O₂ scavenger solution may be any given concentration to be appropriately set according to, for example, a thickness of the EML 14, so that density of the ¹O₂ scavenger 31 in the EML 14 distributes to be desired density.

Next, the EML 14 is supplied, and impregnated, with the ¹O₂ scavenger solution (Step S31, a ¹O₂ scavenger solution supplying step). Note that Step S21 may be carried out before Step S31.

At Step S31, first, the ¹O₂ scavenger solution is delivered in droplets on the EML 14 not containing the ¹O₂ scavenger. Hence, the ¹O₂ scavenger solution is applied to the EML 14. Hence, the EML 14 is impregnated with the ¹O₂ scavenger solution. The ¹O₂ scavenger solution is applied by, for example, spin coating.

Next, for example, heat is applied to the EML 14 to which the ¹O₂ scavenger solution is applied, so as to remove the solvent contained in the applied ¹O₂ scavenger solution (Step S32, a solvent removing step). Hence, the EML 14 containing the QDs 21 and the ¹O₂ scavenger 31 is formed.

After that, as seen in the method for manufacturing the light-emitting element 1, Step S5 (the ETL forming step) and Step S6 (the cathode forming step) are carried out. This is how the light-emitting element 41 illustrated in FIG. 3 is formed.

The method for manufacturing the light-emitting element 41 is the same as that of the light-emitting element 1 according to the first embodiment, except for the points described above.

Specific Example of Method for Manufacturing Light-Emitting Element 41. Described next will be an example of the method for manufacturing the light-emitting element 41 illustrated in FIG. 3.

In this embodiment, as an example, an ITO layer to serve as the anode 11 is formed on the substrate 10 sized in a square of 25 mm by 25 mm and serving as a support. Next, a solution containing PEDOT:PSS is applied to the ITO layer by spin coating. Then, the solution is baked and the solvent is vaporized. Hence, a PEDOT:PSS layer is formed to serve as the HIL 12. Next, a solution containing TFB is applied to the PEDOT:PSS layer by spin coating. Then, the solution is baked and the solvent is vaporized. Hence, a TFB layer is formed as the HTL 13.

On the other hand, QDs serving as the QDs 21 and having a core-shell structure of InP/ZnS with a number-average particle size (diameter) of 10 nm are dispersed in hexane serving as a solvent, so that the QDs have a concentration of 13 mg/mL. Thus, prepared is a QD-dispersed liquid containing the QDs and the solvent.

Then, the QD-dispersed liquid is applied to the TFB layer by spin coating at a rotational speed of 200 rpm for 30 seconds. After that, the QD-dispersed liquid is baked at 80° C. for 10 minutes, and the hexane is vaporized. Hence, on the TFB layer, a QD layer containing the QDs is formed as the EML 14 to have a thickness of, for example, 20 nm.

On the other hand, the DABCO serving as the ¹O₂ scavenger 31 is dispersed in the IPA serving as the solvent, so the DABCO has a concentration of 20 mg/mL. Hence, a DABCO-IPA solution to serve as a ¹O₂ scavenger is prepared to have a concentration of 20 mg/mL.

Then, 200 μL of the DABCO-IPA solution is delivered in droplets to the QD layer formed on the substrate 10 sized in a square of 25 mm by 25 mm. In 30 seconds, the DABCO-IPA solution is applied by spin coating at a rotational speed of 3,000 rpm for 60 seconds. Furthermore, immediately after the spin coating starts, during the spin coating, 200 mL of the IPA serving as a rinse liquid is delivered in droplets three times (i.e., 600 μL in total). Thus, the QD layer is rinsed, and excess DABCO is removed.

After that, the rinsed QD layer is baked at 80° C. for 10 minutes, and the IPA is vaporized. Thus, the EML 14 containing the QDs 21 and the ¹O₂ scavenger 31 is formed.

Next, a dispersion liquid containing ZnMgO nanoparticles is applied to the QD layer by spin coating. Then, the dispersion liquid is baked and the solvent is vaporized. Hence, a ZnMgO nanoparticle layer is formed to serve as the ETL 15. Then, on the ZnO nanoparticle layer, an Al layer is formed to serve as the cathode 16.

The DABCO permeates through, and is mixed in, the QD layer. Even though some of the DABCO is left on the surface of the QD layer, the left DABCO does not form a DABCO layer on the QD layer. Hence, the DABCO hardly increases a thickness of the multilayer stack.

Furthermore, the added DABCO is left in the QD layer with the density of the DABCO distributed. The density of the DABCO is higher upwards of the QD layer (toward the ZnMgO nanoparticle layer) than downwards of the QD layer. The density of the DABCO is higher as the DABCO is found more upwards of the QD layer. Note that, here, the term “upwards” means, in the QD layer, above the center of the QD layer in the thickness direction (a portion close to the ZnMgO nanoparticle layer). The term “downwards” means, in the QD layer, below the center of the QD layer in the thickness direction (a portion away from the ZnMgO nanoparticle layer).

Advantageous Effects

As described above, the light-emitting element 41 illustrated in FIG. 3 has features as follows: for example, the ETL 15; that is, the first functional layer adjacent to the EML 14, contains an oxygen-element-containing compound, and the EML 14 contains the ¹O₂ scavenger 31. Furthermore, in the EML 14, the density of the ¹O₂ scavenger 31 is higher in a portion closer to the ETL 15 with respect to the center of the EML 14 in the thickness direction than in a portion farther away from the ETL 15 with respect to the center of the EML 14 in the thickness direction. More specifically, the density of the ¹O₂ scavenger 31 in the EML 14 is higher toward the ETL 15 in the thickness direction of the EML 14.

Hence, according to this embodiment, the ¹O₂ can be efficiently captured in a portion included in the EML 14 and close to the ETL 15 containing the oxygen-element-containing compound.

In this embodiment, in the EML 14, a content ratio of the ¹O₂ scavenger 31 per 1 part by weight of the QDs 21 is preferably within a range of 0.001 parts by weight or more and 1 part by weight or less because of the same reasons described in the first embodiment.

Note that this embodiment can reduce usage of the ¹O₂ scavenger 31, compared with a case where the same conditions are assumed except that the ¹O₂ scavenger 31 is uniformly mixed throughout the EML 14.

The larger the proportion of the ¹O₂ scavenger 31 is in the EML 14, the greater the influence is on how well the EML 14 is deposited and how rough the surface of the EML 14 is. Hence, an increase in usage of the ¹O₂ scavenger 31 might adversely affect light to be emitted. However, this embodiment can reduce the usage of the ¹O₂ scavenger 31 as described above. Such a feature can reduce the above adverse effects that the ¹O₂ scavenger 31 has on the EML 14. In addition, the feature can reduce expenses of materials and costs for manufacturing the light-emitting element.

Note that, in this embodiment, as a result of supplying the ¹O₂ scavenger solution to the EML 14, a content ratio of the ¹O₂ scavenger 31 per 1 part by weight of the QDs 21 in the EML 14 is a content ratio of the ¹O₂ scavenger 31, which permeates through the EML 14, to the QDs 21. In this embodiment, a rinse liquid is used to rinse the ¹O₂ scavenger 31. In such a case, the content ratio of the ¹O₂ scavenger 31 permeating through the EML 14 indicates a content ratio of the ¹O₂ scavenger 31 left in the EML 14 after the removal of the ¹O₂ scavenger 31 with the rinse liquid.

According to this embodiment, as described above, the EML 14 is supplied with a ¹O₂ scavenger solution containing the ¹O₂ scavenger 31 and a solvent so that the solution permeates through the EML 14. Such a feature makes it possible to adjust density distribution of the ¹O₂ scavenger 31 in the EML 14.

This embodiment does not form a film mixture of the QDs 21 and the ¹O₂ scavenger 31 with a single liquid of QD-dispersed liquid additionally containing the ¹O₂ scavenger 31. Instead, as described above, this embodiment once forms the EML 14 not containing the ¹O₂ scavenger 31, and supplies the EML 14 with a ¹O₂ scavenger solution so that the ¹O₂ scavenger solution permeates through the EML 14. Hence, the longer the EML 14 and the ¹O₂ scavenger solution are in contact together, the further the ¹O₂ scavenger solution can permeate through the EML 14. Whereas, if the ¹O₂ scavenger is removed immediately after supplied to the EML 14, the ¹O₂ scavenger solution can be supplied only to the vicinity of the surface of the EML 14. As can be seen, the density distribution of the ¹O₂ scavenger 31 can be intentionally adjusted.

Furthermore, the density distribution of the ¹O₂ scavenger 31 can be adjusted according to, for example, viscosity of the ¹O₂ scavenger solution. Hence, the density distribution of the ¹O₂ scavenger 31 can be varied according to the kinds of the solvent and the ¹O₂ scavenger 31 to be used, and also to the concentration of the ¹O₂ scavenger 31 in the ¹O₂ scavenger solution.

Moreover, the density distribution of the ¹O₂ scavenger 31 can be adjusted according to, for example, wettability of a ¹O₂-scavenger-solution-receiving layer supplied with the ¹O₂ scavenger solution, in relation to the ¹O₂ scavenger solution. In this embodiment, the density distribution of the ¹O₂ scavenger 31 can be adjusted according to, for example, wettability of the EML 14 in relation to the ¹O₂ scavenger solution.

When the ¹O₂ scavenger solution is delivered in droplets to the ¹O₂-scavenger-solution-receiving layer, the wettability (a relationship of polarity-nonpolarity between the ¹O₂-scavenger-solution-receiving layer and the ¹O₂ scavenger solution) causes variations in how much the ¹O₂- scavenger-solution-receiving layer is wet with the ¹O₂ scavenger solution (i.e., affinity of the ¹O₂ scavenger solution). The wettability of the ¹O₂ scavenger solution in the ¹O₂-scavenger-solution-receiving layer varies depending not only on the affinity of the ¹O₂ scavenger solution and the ¹O₂-scavenger-solution-receiving layer but also on shapes of the ¹O₂-scavenger-solution-receiving layer (e.g., the sizes, the shapes and the numbers of asperities). If the wettability is poor, the ¹O₂ scavenger solution is less likely to permeate through the ¹O₂-scavenger-solution-receiving layer, and the density distribution of the ¹O₂ scavenger is likely to be uneven. Whereas, if the wettability is good, the ¹O₂ scavenger solution is likely to permeate through the ¹O₂-scavenger-solution-receiving layer, and the density of the ¹O₂ scavenger is less likely to distribute. As a result, the density distribution is close to be uniform. The wettability of the ¹O₂-scavenger-solution-receiving layer can be varied according to, for example, the polarities of the ligands, the lengths of the ligand chains, the particle sizes and shapes of the nanoparticles such as the QDs 21 contained in the ¹O₂-scavenger-solution-receiving layer.

Furthermore, the density distribution of the ¹O₂ scavenger 31 can be adjusted according to, for example, the boiling point of a solvent to be used for the ¹O₂ scavenger solution. Although influenced by the processing environment, a solvent is typically more likely to vaporize as the boiling point is lower. Hence, if the solvent to be used for the ¹O₂ scavenger solution has a low boiling point, the ¹O₂ scavenger solution permeates shallowly into the ¹O₂-scavenger-solution-receiving layer. As a result, the density distribution of the ¹O₂ scavenger 31 is likely to be uneven. Whereas, if the solvent to be used for the solvent solution has a high boiling point, the solvent is less likely to vaporize. As a result, the ¹O₂ scavenger solution permeates deeply into the ¹O₂-scavenger-solution-receiving layer.

Moreover, the density distribution of the ¹O₂ scavenger 31 can be adjusted according to, for example, a processing environment. When the solvent contained in the applied ¹O₂ scavenger solution is removed at Step S32 (the solvent removing step), vaporization of the solvent is encouraged if the solvent is removed (dried) under a reduced pressure and a dry environment. Hence, if Step S32 is carried out under such environments, the density distribution is likely to be uneven. Note that the “dry environment” here indicates a situation in which not only water but also solvent vapor is small in amount.

In addition, the density distribution of the ¹O₂ scavenger 31 can be adjusted according to the temperature of the ¹O₂ scavenger solution and the temperature of a processing environment. Typically, vaporization of the solvent is encouraged further as the temperature of the solution to be used and the temperature of the processing environment are higher. As a result, the density distribution is likely to be uneven.

Furthermore, if the environmental atmosphere is circulated and ventilated, vaporization of the solvent is encouraged. As a result, the density distribution is likely to be uneven. Hence, the density distribution of the ¹O₂ scavenger 31 can be adjusted by, for example, a processing control technique.

As can be seen, the density distribution of the ¹O₂ scavenger 31 can be adjusted by various techniques. With a combination of the above conditions, the ¹O₂ scavenger 31 can be adjusted to exhibit any given density distribution. Note that, here, as described above, the density distribution of the ¹O₂ scavenger 31 does not have to vary linearly.

### Modification

As described above, FIGS. 3 and 4 show an exemplary case where the light-emitting element 41 has a known structure in which the first functional layer is the ETL 15. However, this embodiment shall not be limited to such a case. The light-emitting element 41 may have an inverted structure in which the first functional layer may be the HTL 13. The HTL 13 contains an oxygen-element-containing compound such as nanoparticles of a p-type oxide semiconductor including, for example, NiO. In the EML 14, the density of the ¹O₂ scavenger 31 may be higher in a portion closer to the HTL 13 with respect to the center of the EML 14 in the thickness direction than in a portion farther away from the HTL 13 with respect to the center of the EML 14 in the thickness direction. Such features make it possible to achieve the same advantageous effects as those described above. Here, the density of the ¹O₂ scavenger 31 in the EML 14 may be higher toward the HTL 13. As can be seen, if the first functional layer is the HTL 13, the density distribution of the ¹O₂ scavenger 31 in the EML 14 does not have to increase linearly toward the first functional layer. The density distribution may increase stepwise.

### Third Embodiment

The first and second embodiments exemplify a case where the EML 14 contains the ¹O₂ scavenger 31. However, as described before, the aprotic ¹O₂ scavenger may be contained in at least one of the EML 14 or the first functional layer, both of which are included in the at least one functional layer.

Described below will be an exemplary case where a light-emitting element according to an aspect of the present disclosure includes the EML 14 and the first functional layer both serving as the at least one functional layer, and where the first functional layer is adjacent to the EML 14 and contains the ¹O₂ scavenger 31.

Furthermore, described below will be an exemplary case where the first functional layer is a carrier transport layer, together with an exemplary case where the light-emitting element has a known structure and where the carrier transport layer serving as the first functional layer is the ETL 15.

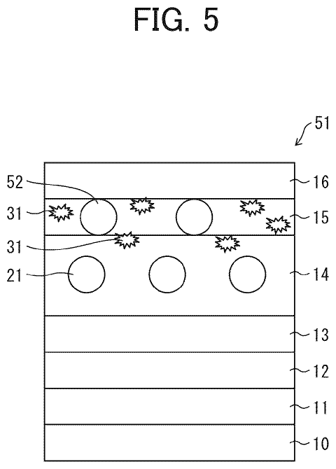

FIG. 5 is a cross-sectional view schematically illustrating an example of a light-emitting element 51 according to this embodiment.

The light-emitting element 51 illustrated in FIG. 5 includes, for example: the anode 11; the HIL 12; the HTL 13; the EML 14; the ETL 15; and the cathode 16, all of which are sequentially arranged from below as seen in the light-emitting elements described in the first and second embodiments. Furthermore, similar to the light-emitting elements described in the first and second embodiments, the ETL 15 contains, as an oxygen-element-containing ETL material (an oxygen-element-containing compound), nanoparticles 52 of, for example, either an n-type metal oxide such as ZnO and ZnMgO or an oxygen-element-containing organometallic complex such as Alq3.

Note that, in the light-emitting element 51 illustrated in FIG. 5, the ¹O₂ scavenger 31 is mixed in the ETL 15. The light-emitting element 51 is different from the light-emitting elements described in the first and second embodiments in this point.

In this embodiment, in the ETL 15, a content ratio of the ¹O₂ scavenger 31 per 1 part by weight of the nanoparticles 52 is preferably within a range of 0.001 parts by weight or more and 1 part by weight or less. In the ETL 15, if the content ratio of the ¹O₂ scavenger 31 per 1 part by weight of the nanoparticles 52 exceeds 1 part by weight, the ETL 15 might deteriorate in film quality. Whereas, in the ETL 15, if the content ratio of the ¹O₂ scavenger 31 per 1 part by weight of the nanoparticles 52 is less than 0.001 parts by weight, a sufficient amount of ¹O₂ cannot be captured. Hence, uncaptured ¹O₂ might enter the EML 14 and degrade the QDs 21. As a result, degradation of the QDs 21 by ¹O₂ might not be sufficiently reduced.

### Method for Manufacturing Light-Emitting Element 51

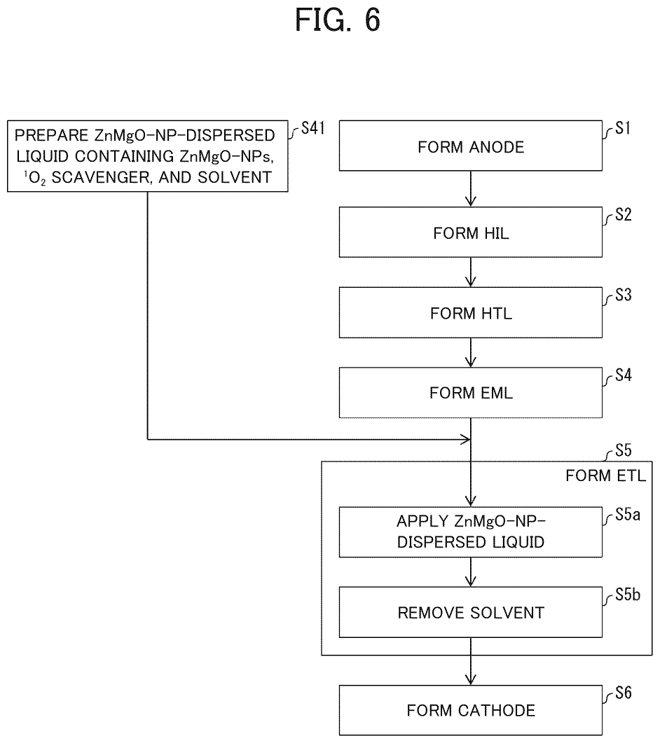

FIG. 6 is a flowchart showing a method for manufacturing the light-emitting element 51 illustrated in FIG. 5.

The method for manufacturing the light-emitting element 51 illustrated in FIG. 5 involves Step S1 (the anode forming step) to Step S4 (the EML forming step) in FIG. 6, as seen in the method for manufacturing the light-emitting element 1 described before. So far, the method is the same as a method for manufacturing a typical QLED.

On the other hand, an ETL-material-dispersed liquid serving as an oxygen-element-containing compound is prepared (manufactured) to contain: an ETL material including the nanoparticles 52; the ¹O₂ scavenger 31; and a solvent (Step S41, an ETL-material-dispersed-liquid preparing step). As shown in FIG. 6, examples of the nanoparticles 52 (the ETL material) include ZnMgO nanoparticles (hereinafter referred to as “ZnMgO-NPs”). In this embodiment, as an example, a ZnMgO-NP-dispersed liquid serving as the ETL-material-dispersed-liquid is prepared to contain the ZnMgO-NP, the ¹O₂ scavenger 31, a solvent as shown in FIG. 6.

The solvent is, for example, an amphoteric solvent such as IPA or ethanol. In the ETL-material-dispersed liquid, concentration of the ETL material may be any given concentration to be appropriately set according to, for example, a design value of a thickness of the ETL 15.

In the ETL-material-dispersed liquid, a content ratio of the ¹O₂ scavenger 31 per 1 part by weight of the nanoparticles 52 is set so that, in the ETL 15, the content ratio of the ¹O₂ scavenger 31 per 1 part by weight of the nanoparticles 52 is preferably within a range of 0.001 parts by weight or more and 1 part by weight or less. Hence, in the ETL-material-dispersed liquid, the content ratio of the ¹O₂ scavenger 31 per 1 part by weight of the nanoparticles 52 is set within a range of, for example, 0.001 parts by weight or more and 1 part by weight or less. In the ETL-material-dispersed liquid, if the content ratio of the ¹O₂ scavenger 31 per 1 part by weight of the nanoparticles 52 exceeds 1 part by weight, the ETL 15 to be formed might deteriorate in film quality. Whereas, in the ETL-material-dispersed liquid, if the content ratio of the ¹O₂ scavenger 31 per 1 part by weight of the nanoparticles 52 is less than 0.001 parts by weight, the ¹O₂ cannot be captured in sufficient amount. Hence, uncaptured ¹O₂ might enter the EML 14 and degrade the QDs 21. As a result, degradation of the QDs 21 by ¹O₂ might not be sufficiently reduced. Next, the ETL 15 is formed of the ETL-material-dispersed liquid (e.g., the ZnMgO-NP dispersed liquid) (Step S5, the ETL forming step). Note that Step S41 may be carried out before Step S5.

At Step S41, first, the ETL-material-dispersed liquid (e.g., the ZnMgO-NP dispersed liquid) is applied to the EML 14 serving as an underlayer of the ETL 14 (Step S5a, an ETL-material-dispersed liquid applying step). Thus, a coat of the ETL-material-dispersed liquid is formed. The ETL-material-dispersed liquid is applied by, for example, spin coating.

Next, for example, heat is applied to the coat to remove a solvent contained in the coat (i.e., the applied ETL-material-dispersed liquid), and to dry the coat (Step S5b, a solvent removing step). Hence, the ETL 15 containing the ¹O₂ scavenger 31 and the nanoparticles 52 is formed.

Note that the nanoparticles 52 may be coordinated with ligands. The ETL-material- dispersed liquid and the ETL 15 may contain known ligands to serve as the ligands. After that, the cathode 16 is formed (Step S6, the cathode forming step). This is how the light-emitting element 51 illustrated in FIG. 5 is formed.

The method for manufacturing the light-emitting element 51 is the same as a typical method for manufacturing a QLED except that the ¹O₂ scavenger 31 is added to the ETL-material-dispersed liquid.

### Specific Example of Method for Manufacturing Light-Emitting Element 51

Described next will be an example of the method for manufacturing the light-emitting element 51 illustrated in FIG. 5.

In this embodiment, as an example, an ITO layer to serve as the anode 11 is formed on the substrate 10. Next, a solution containing the PEDOT:PSS is applied to the ITO layer by spin coating. Then, the solution is baked and the solvent is vaporized. Hence, a PEDOT:PSS layer is formed as the HIL 12. Next, a solution containing the TFB is applied to the PEDOT:PSS layer by spin coating. Then, the solution is baked and the solvent is vaporized. Hence, a TFB layer is formed as the HTL 13.

On the other hand, QDs serving as the QDs 21 and having a core-shell structure of InP/ZnS with a number-average particle size (diameter) of 10 nm are dispersed in hexane serving as a solvent, so that the QDs have a concentration of 13 mg/mL. Thus, prepared is a QD-dispersed liquid containing the QDs and the solvent.

Then, the QD-dispersed liquid is applied to the TFB layer by spin coating at a rotational speed of 200 rpm for 30 seconds. After that, the QD-dispersed liquid is baked at 80° C. for 10 minutes, and the hexane is vaporized. Hence, on the TFB layer, a QD layer containing the QDs is formed as the EML 14 to have a thickness of, for example, 20 nm.

On the other hand, ZnMgO-NPs serving as the nanoparticles 52 with a number-average particle size (diameter) of 10 nm are dispersed in ethanol serving as a solvent, so that the ZnMgO-NPs have a concentration of 25 mg/mL. Next, the DABCO serving as the ¹O₂ scavenger 31 is added to the obtained dispersed liquid at a rate of 10 mg/mL with respect to the above ethanol. Thus, prepared is a ZnMgO-NP dispersed liquid in which 1 mL of ethanol contains 10 mg of the DABCO with respect to 25 mg of ZnMgO-NPs.

Then, the ZnMgO-NP dispersed liquid is applied to the QD layer by spin coating at a rotational speed of 200 rpm for 30 seconds. After that, the ZnMgO-NP dispersed liquid is baked at 80° C. for 10 minutes, and the ethanol is vaporized. Hence, on the QD layer, the ETL 15 containing the ZnMgO-NPs and the DABCO is formed to have a thickness of, for example, 50 nm. Then, on the ETL 15, an Al layer is formed to serve as the cathode 16.

### Advantageous Effects

According to this embodiment, as described above, the at least one functional layer includes, for example, the EML 14 and the first functional layer. The first functional layer is adjacent to the EML 14, and includes the ¹O₂ scavenger 31. Such features make it possible to reduce the risk that ¹O₂ enters the EML 14.

In particular, a carrier transport material (an oxygen-element-containing compound) containing an oxygen element can serve as a light source of ¹O₂. Here, the carrier transport material includes such materials as nanoparticles of a metal oxide and nanoparticles of an organometallic complex containing an oxygen element. The nanoparticles 52 such as ZnMgO also function as a photosensitizer, and thus generate ¹O₂. The QDs 21 and the nanoparticles 52 such as ZnMgO are in contact with each other at an interface of the stack. Hence, the ¹O₂ moves from the ETL 15 to the EML 14, and oxidizes the QDs 21.

However, as described above, for example, the ETL 15 contains an aprotic ¹O₂ scavenger serving as the ¹O₂ scavenger 31. Such a feature makes it possible to reduce the risk that ¹O₂ in the ETL 15 enters the EML 14. Furthermore, the ETL 15 contains the aprotic ¹O₂ scavenger serving as the ¹O₂ scavenger 31. Compared with a case where the EML 14 contains the aprotic ¹O₂ scavenger, such a feature can reduce adverse effects that the aprotic ¹O₂ scavenger has on the EML 14.

Note that, in the second embodiment, the ¹O₂ scavenger solution and the EML 14 are in contact with each other for a certain period of time so that the ¹O₂ scavenger solution permeates through the EML 14. However, at Step S5a (the ETL-material-dispersed liquid applying step), the ETL-material-dispersed liquid is applied to the EML 14, and the time period is extremely short for the ETL-material-dispersed liquid and the EML 14 in contact with each other regardless of whether spin coating or inkjet printing is used for the application. Hence, FIG. 5 illustrates an example in which the EML 14 slightly contains the ¹O₂ scavenger 31. However, it may be understood that the ¹O₂ scavenger 31 hardly permeates through the EML 14.

### First Modification

As described above, this embodiment also describes an exemplary case where the light-emitting element 51 has a known structure in which the first functional layer is the ETL 15. However, this embodiment shall not be limited to such a case.

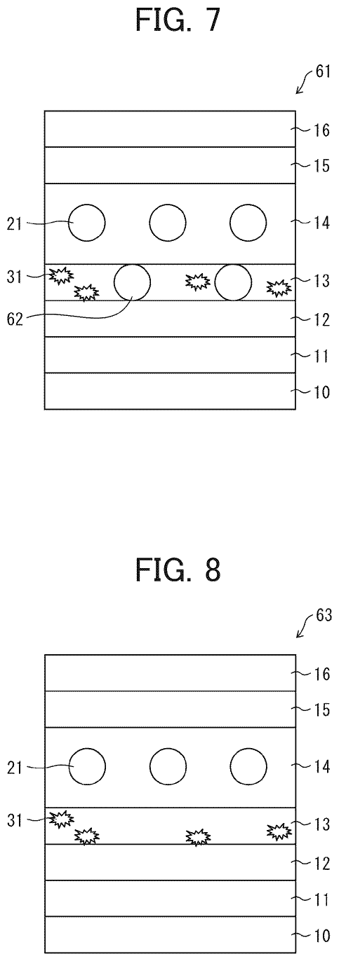

FIG. 7 is a cross-sectional view schematically illustrating an example of a light-emitting element 61 according to a first modification.

The light-emitting element 61 illustrated in FIG. 7 includes, for example: the anode 11; the HIL 12; the HTL 13; the EML 14; the ETL 15; and the cathode 16, all of which are sequentially arranged from below as seen in the light-emitting element 51 illustrated in FIG. 5. In this modification, the HTL 13 contains nanoparticles 62 including, for example, a p-type metal oxide such as NiO. The nanoparticles 62 serve as an HTL material containing an oxygen element (an oxygen-element-containing compound). In the light-emitting element 61 illustrated in FIG. 7, the ¹O₂ scavenger 31 is mixed in the HTL 13.

As described before, a carrier transport material (an oxygen-element-containing compound) containing an oxygen element can serve as a light source of ¹O₂. Here, the carrier transport material includes such materials as nanoparticles of a metal oxide and nanoparticles of an organometallic complex containing an oxygen element. The nanoparticles such as NiO also function as a photosensitizer, and thus generate ¹O₂. Hence, when the HTL 13 adjacent to the QDs 21 contains, as described above, the nanoparticles 62 such as NiO serving as the HTL material containing an oxygen element (an oxygen-element-containing compound), the ¹O₂ moves from the HTL 13 to the EML 14 and oxidizes the QDs 21. Thus, the first functional layer may be the HTL 13.

In any case, the first functional layer contains an aprotic ¹O₂ scavenger serving as the ¹O₂ scavenger 31. Such a feature makes it possible to reduce the risk that ¹O₂ in the first functional layer enters the EML 14. Furthermore, the first functional layer contains the aprotic ¹O₂ scavenger serving as the ¹O₂ scavenger 31. Compared with a case where the EML 14 contains the aprotic ¹O₂ scavenger, such a feature can reduce adverse effects that the aprotic ¹O₂ scavenger has on the EML 14.

Note that, regardless of whether the first functional layer is the ETL 15 or the HTL 13, in the first functional layer, a content ratio of the ¹O₂ scavenger 31 per 1 part by weight of the nanoparticles is preferably within a range of 0.001 parts by weight or more and 1 part by weight or less because of the same reasons described above.

Moreover, as described above, regardless of whether the first functional layer is the ETL 15 or the HTL 13, the functional layer forming step includes: a step of forming the EML 14 containing the QDs 21; and a step of forming the first functional layer containing the ¹O₂ scavenger 31. Such a feature can reduce adverse effects that the aprotic ¹O₂ scavenger 31 has on the EML 14.

### Second Modification

FIGS. 5 and 7 show a case where the first functional layer adjacent to the EML 14 is a carrier transport layer, and where the carrier transport layer contains the ¹O₂ scavenger 31 together with the carrier transport material containing an oxygen element (an oxygen-element-containing compound). However, a light-emitting element according to this embodiment shall not be limited to such a case.

The light-emitting element according to this embodiment may include, for example: the EML 14; the first functional layer; and a second functional layer provided between the first electrode and the first functional layer, all of which serve as the at least one functional layer. The second functional layer may contain an oxygen-element-containing compound. The first functional layer may contain the ¹O₂ scavenger 31.

Described below as an example will be a case where the first functional layer is the HTL 13 and the second functional layer is the HIL 12.

FIG. 8 is a cross-sectional view schematically illustrating an example of a light-emitting element 63 according to this modification.

The light-emitting element 63 illustrated in FIG. 8 includes, for example: the anode 11; the HIL 12; the HTL 13; the EML 14; the ETL 15; and the cathode 16, all of which are sequentially arranged from below as seen in the light-emitting elements described in the first and second embodiments. As described before, the HIL 12 is formed of, for example, the PEDOT:PSS as an HIL material. The PEDOT:PSS is an HIL material containing an oxygen-element (an oxygen-element-containing compound). As can be seen, when the second functional layer is, for example, the HIL 12, and the HIL 12 contains an oxygen-element-containing compound, the HTL 13 serving as the first functional layer may contain the ¹O₂ scavenger 31 as illustrated in FIG. 8. In this case, the HTL 13 may be formed of an oxygen-element-free HTL material such as the TFB.

As can be seen, when the second functional layer contains the oxygen-element-containing compound and the first functional layer contains the ¹O₂ scavenger 31, the first functional layer can catch the ¹O₂ before the ¹O₂ moves from the second functional layer to the EML 14. Furthermore, also in this case, not the EML 14 but the first functional layer contains the ¹O₂ scavenger 31. Such a feature can reduce adverse effects that the ¹O₂ scavenger 31 has on the EML 14.

Moreover, here, in the first functional layer (e.g., the HTL 13 in FIG. 8), density of the ¹O₂ scavenger 31 is preferably higher in a portion closer to the second functional layer (e.g., the HIL 12 in FIG. 8) with respect to a center of the first functional layer in a thickness direction than in a portion farther away from the second functional layer with respect to the center of the first functional layer in the thickness direction. In such a case, for example, the density of the ¹O₂ scavenger 31 in the first functional layer is desirably higher toward the second functional layer (e.g., the HIL 12 in FIG. 8) in the thickness direction of the first functional layer. Note that, here, the density distribution of the ¹O₂ scavenger 31 in the first functional layer does not have to increase linearly toward the second functional layer. The density distribution may increase stepwise. In the present disclosure, the density of the ¹O₂ scavenger 31 in the first functional layer is higher toward the second functional layer. This statement means that the density of the ¹O₂ scavenger 31 in the first functional layer may be higher linearly or stepwise toward the second functional layer in the thickness direction of the first functional layer.

Thanks to such a feature, the ¹O₂ can be efficiently captured in a portion included in the first functional layer and close to the second functional layer containing the oxygen-element-containing compound. Furthermore, the feature makes it possible to reduce usage of the ¹O₂ scavenger 31, compared with a case where the same conditions are assumed except that the ¹O₂ scavenger 31 is uniformly mixed throughout the first functional layer. The reduction in the usage of the ¹O₂ scavenger 31 can reduce adverse effects that the ¹O₂ scavenger 31 has, and also reduce expenses of materials and manufacturing costs.

### Third Modification

FIGS. 5, 7, and 8 show an exemplary case where the light-emitting element according to this embodiment has a known structure. However, in this embodiment, the light-emitting element may also have an inverted structure. Hence, even if the light-emitting element has an inverted structure, the first functional layer may be either the HTL 13 or the ETL 15.

### Fourth Embodiment

As described above, if a light-emitting element includes the EML 14 and the first functional layer both serving as at least one functional layer, and the first functional layer contains the ¹O₂ scavenger 31 and the oxygen-element-containing compound, the first functional layer shall not be limited to a layer having a carrier-transporting function as described in the third embodiment. The first functional layer may be any one of the ETL15, an electron injection layer (hereinafter referred to as an “EIL”), the HTL13, the HIL, and an intermediate layer.

Here, the “intermediate layer” is a functional layer other than the ETL15, the EIL, the HTL13, and the HIL, and additionally included for various purposes. Note that the ETL 15 may be an electron-transport-injection layer. Furthermore, either the HTL 13 or the HIL may be a hole-transport-injection layer.

Examples of the various purposes include passivation, carrier balance adjustment (e.g., prevention of excessive injection of carriers into the EML 14 because of insertion of an insulator), improvement in wettability, and reduction in reaction of interlayer materials (e.g., interactions such as quenching and deterioration due to chemical reaction).

Examples of the material of the intermediate layer include a metal oxide and a self-assembled film (a self-assembled monolayer, hereinafter referred to as a “SAM”).

As described before, the ETL 15 contains, as an ETL material containing an oxygen element (an oxygen-element-containing compound), the nanoparticles 52 of, for example, either an n-type metal oxide such as ZnO and ZnMgO or an oxygen-element-containing organometallic complex such as such as Alq3. Furthermore, the HTL 13 contains nanoparticles 62 including, for example, a p-type metal oxide such as NiO. The nanoparticles 62 serve as an HTL material containing an oxygen element (an oxygen-element-containing compound). Note that the third embodiment exemplifies a case where, as a modification, the HTL material containing an oxygen element (an oxygen-element-containing compound) is the nanoparticles 62 including a p-type metal oxide such as NiO as described above. However, an organic hole-transporting material such as the V886 or the HN-D1 is also the HTL material containing an oxygen element (an oxygen-element-containing compound). Furthermore, the HTL 12 is formed of, for example, the PEDOT:PSS serving as the HIL material containing an oxygen element (an oxygen-element-containing compound). Moreover, the intermediate layer may be a passivation layer containing such an oxygen element as, for example, Al₂O₃. Examples of the SAM to be used for the intermediate layer include a film formed of: 2-(3,6-dimethoxy)-9H-carbazol-9-yl) ethyl]phosphonate (MeO-2PACz); [2-(9H-carbazol-9-yl)ethyl]phosphonate (2PACz); and a silane coupling agent.

In addition, as described above, if any one of the functional layers around the ETL15, such as the ETL 15, the EIL, the HTL 13, the HIL, and the intermediate layer, includes the oxygen-element-containing compound, the functional layer containing the oxygen-element-containing compound may further contain a crosslinking agent.

The crosslinking agent may be either a photo-crosslinking agent or a thermal-crosslinking agent. Example of the crosslinking agent includes a crosslinking agent having at least one epoxy group. Examples of the crosslinking agent include: 1,2-epoxyoctane; and diglycidyl-1,2-cyclohexanedicarboxylate.

These crosslinking agents may contain, for example, an epoxy group described above to serve as a functional group that is likely to chemically react with light and heat. The crosslinking agent may be mixed in any layer. These crosslinking agents may be used for crosslinking, for example, the EML 14 and the HTL 13 so that the EML 14 and the HTL 13 are chemically stabilized.

Described below will be a specific example of a light-emitting element according to this embodiment.

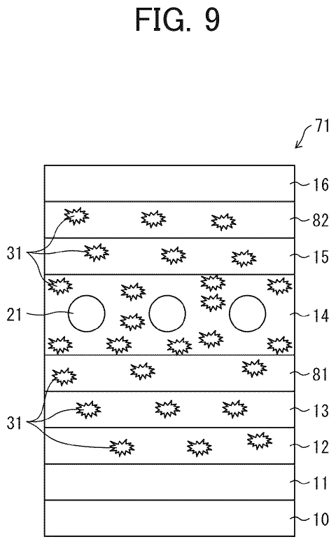

FIG. 9 is a cross-sectional view schematically illustrating an example of a light-emitting element 71 according to this embodiment.

The light-emitting element 71 illustrated in FIG. 9 includes: the anode 11; the HIL 12; the HTL 13; an SAM 81; the EML 14; the ETL 15; an EIL 82; and the cathode 16, all of which are sequentially arranged from below.

Note that FIG. 9 illustrates an exemplary case where the light-emitting element 71 has a known structure. However, this embodiment shall not be limited to such a case. The light-emitting element 71 may also have an inverted structure.

Furthermore, FIG. 9 exemplifies a case where all the functional layers between the anode 11 and the cathode 16 contain the ¹O₂ scavenger 31.

The light-emitting element 71 illustrated in FIG. 9 includes, as described above, the SAM 81 serving as an intermediate layer and the EIL 82 between the anode 11 and the cathode 16. All the functional layers between the anode 11 and the cathode 16 contain the ¹O₂ scavenger 31. Otherwise, the light-emitting element 71 illustrated 9 has the same configuration as the configurations of the light-emitting elements according to the first to third embodiments.

The EIL 82 is a charge injection layer containing, as a functional material, an EIL material capable of transporting electrons (an electron-transporting material). The EIL 82 has an electron injection function to enhance efficiency in injecting the electrons from the cathode 16 into the ETL 15. The EIL 82 can be formed of a known electron-transporting material to serve as an EIL material. The EIL 82 may contain, for example, Alq3 to serve as an oxygen-element-containing compound. Furthermore, as described above, the EIL 82 may contain, for example, an epoxy-group-containing crosslinking agent to serve as a crosslinking agent. The EIL 82 can be formed by the same technique used for the ETL 15

The SAM 81 illustrated in FIG. 9 is a buffer layer capable of transporting the holes. The SAM 81 is used to improve hole transporting capability, as well as wettability of a QD-dispersed liquid to be applied to the SAM 81. In addition, the SAM 81 functions as a buffer layer to prevent the QDs 21 from chemically deteriorating when an HTL material such as NiO and the QDs 21 are in direct contact with each other. The SAM 81 is provided between the anode 11 and the EML 14 (e.g., between the HTL 13 and the EML 14 as illustrated in FIG. 9). As a material of the SAM 81, for example, an organic insulating material can be used. Furthermore, the material of the SAM 81 may also be a hole-transporting material.

Described below will be a method for forming the SAM 81, showing as an example a case where the SAM 81 is a self-assembled film formed of MeO-2PACz and where the HTL 13 to serve as an underlayer of the SAM 81 contains NiO nanoparticles serving as the nanoparticles 62.

In forming the SAM 81, an EBL material solution containing an EBL material is applied to the HTL 13 by, for example, spin coating. Then, the EBL material solution is baked and the solvent is vaporized. Hence, the SAM 81 is successfully formed.

In this embodiment, the MeO-2PACz serving as an EBL material solution is dispersed in ethanol serving as a solvent, so that the MeO-2PACz has a concentration of 0.01 mol/L. Hence, a MeO-2PACz-ethanol solution is prepared to serve as the EBL material solution. Next, the MeO-2PACz-ethanol solution is applied to, for example, a NiO-NP layer formed as the HTL 13 and provided on the substrate 10 sized in a square of 25 mm by 25 mm. The MeO-2PACz-ethanol solution is applied by spin coating at a rotational speed of 300 rpm for 30 seconds. After that, the MeO-2PACz-ethanol solution is baked at 100° C. for 10 minutes, and the ethanol is vaporized. Hence, on the NiO-NP layer, a MeO-2PACz layer is formed to serve as the SAM 81.

The ¹O₂ scavenger 31 may be mixed in the MeO-2PACz layer as follows. For example, after the MeO-2PACz layer is formed, the PACz layer may be supplied with a ¹O₂ scavenger solution as described in the second embodiment. After that, the solvent contained in the supplied ¹O₂ scavenger solution may be removed. Furthermore, the ¹O₂ scavenger 31 may be added to the MeO-2PACz-ethanol solution so that the SAM 81 may be formed to contain the MeO-2PACz and the ¹O₂ scavenger 31.

In any case, in each of the functional layers, a content ratio of the ¹O₂ scavenger 31 per 1 part by weight of the oxygen-element-containing compound is preferably within a range of 0.001 parts by weight or more and 1 part by weight or less because of the same reasons described in the first to third embodiments.

Note that FIG. 9 exemplifies a case where all the functional layers between the anode 11 and the cathode 16 contain the ¹O₂ scavenger 31. However, the light-emitting element 1 according to an aspect of the present disclosure may include at least one layer containing the ¹O₂ scavenger 31 between the anode 11 and the cathode 16. Hence, at the step of forming a functional layer, at least one layer containing the ¹O₂ scavenger 31 may be formed.

Moreover, FIG. 9 exemplifies a case where the intermediate layer is the SAM 81. As described before, the intermediate layer is a functional layer other than the ETL15, the EIL, the HTL 13, and the HIL, and additionally included for various purposes. The intermediate layer may be, for example, either a hole-blocking layer or an electron-blocking layer. Alternatively, the intermediate layer may be a passivation layer.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

### REFERENCE SIGNS LIST

1, 41, 51, 61, 63, and 71 Light-Emitting Elements
11 Anode (First Electrode or Second Electrode)
12 HIL (Functional Layer, First Function Layer, and Second Functional Layer)
13 HTL (Functional Layer and First Functional Layer)
14 EML (Light-Emitting Layer)
15 ETL (Functional Layer and First Functional Layer)
16Cathode (First Electrode or Second Electrode)
21 QDs (Quantum Dots)
31 ¹O₂ Scavenger
52 and 62 Nanoparticles
81 SAM (Intermediate Layer, Functional Layer, and First Functional Layer)
82 EIL (Functional Layer, First Function Layer, and Second Functional Layer)

1. A light-emitting element, comprising:
a first electrode and a second electrode; and
at least one functional layer provided between the first electrode and the second electrode, and containing an aprotic singlet oxygen scavenger.

2. The light-emitting element according to claim 1,
wherein the aprotic singlet oxygen scavenger includes at least one compound selected from the group consisting of: a tertiary amine; carotenoid; an ethylenic compound; naphthalene and a derivative of naphthalene; and anthracene and a derivative of anthracene.

3. The light-emitting element according to claim 1,
wherein the aprotic singlet oxygen scavenger includes a tertiary amine.

4. The light-emitting element according to claim 3,
wherein the tertiary amine includes at least one selected from the group consisting of: 1,4-diazabicyclo[2.2.2]octane; triethylamine; and N,N-dimethylaniline.

5. The light-emitting element according to claim 1,
wherein the aprotic singlet oxygen scavenger is a monomer.

6. The light-emitting element according to 1,
wherein the at least one functional layer includes a light-emitting layer containing quantum dots, and
the light-emitting layer contains the aprotic singlet oxygen scavenger.

7. The light-emitting element according to claim 6,
wherein, in the light-emitting layer, a content ratio of the aprotic singlet oxygen scavenger per 1 part by weight of the quantum dots is within a range of 0.001 parts by weight or more and 1 part by weight or less.

8. The light-emitting element according to claims 1,
wherein the at least one functional layer includes a light-emitting layer containing quantum dots and a first functional layer other than the light-emitting layer, and
the first functional layer is adjacent to the light-emitting layer, and contains the aprotic singlet oxygen scavenger.

9. The light-emitting element according to claim 8,
wherein the first functional layer has a carrier-transporting function, and
the first functional layer contains at least one kind of nanoparticles including at least one selected from the group consisting of: nanoparticles of a metal oxide; and nanoparticles of an organometallic complex containing an oxygen element.

10. The light-emitting element according to claim 9,
wherein the nanoparticles are nanoparticles of a metal oxide including at least one selected from the group consisting of: zinc oxide; zinc magnesium oxide; and nickel oxide.

11. The light-emitting element according to claim 10,
wherein the first functional layer has an electron-transporting function, and the nanoparticles are nanoparticles of zinc magnesium oxide.

12. The light-emitting element according to claim 9,
wherein, in the first functional layer, a content ratio of the aprotic singlet oxygen scavenger per 1 part by weight of the nanoparticles is within a range of 0.001 parts by weight or more and 1 part by weight or less.

13. The light-emitting element according to claim 8,
wherein the light-emitting layer further contains the aprotic singlet oxygen scavenger.

14. The light-emitting element according to claim 13,
wherein, in the light-emitting layer, a content ratio of the aprotic singlet oxygen scavenger per 1 part by weight of the quantum dots is within a range of 0.001 parts by weight or more and 1 part by weight or less.

15. The light-emitting element according to claim 1,
wherein the at least one functional layer includes a light-emitting layer containing quantum dots and a first functional layer other than the light-emitting layer,
the first functional layer contains: the aprotic singlet oxygen scavenger; and an oxygen-element-containing compound,
the first functional layer is any one of: an electron transport layer; an electron injection layer; a hole transport layer; a hole injection layer; and an intermediate layer, and
in the first functional layer, a content ratio of the aprotic singlet oxygen scavenger per 1 part by weight of the oxygen-element-containing compound is within a range of 0.001 parts by weight or more and 1 part by weight or less.

16-17. (canceled)

18. The light-emitting element according to claim 1,
wherein the at least one functional layer includes a light-emitting layer containing quantum dots and a first functional layer other than the light-emitting layer,
the first functional layer is adjacent to the light-emitting layer, and contains an oxygen-element-containing compound,
the light-emitting layer contains the aprotic singlet oxygen scavenger, and
in the light-emitting layer, density of the aprotic singlet oxygen scavenger is higher in a portion closer to the first functional layer with respect to a center of the light-emitting layer in a thickness direction than in a portion farther away from the first functional layer with respect to the center of the light-emitting layer in the thickness direction.

19. The light-emitting element according to claim 18,
wherein the density of the aprotic singlet oxygen scavenger in the light-emitting layer is higher toward the first functional layer in the thickness direction of the light-emitting layer.

20. The light-emitting element according to claim 1,
wherein the at least one functional layer includes a light-emitting layer containing quantum dots, a first functional layer other than the light-emitting layer and a second functional layer
the second functional layer contains an oxygen-element-containing compound, and
the first functional layer contains the aprotic singlet oxygen scavenger.

21. The light-emitting element according to claim 20,
wherein, in the first functional layer, density of the aprotic singlet oxygen scavenger is higher in a portion closer to the second functional layer with respect to a center of the first functional layer in a thickness direction than in a portion farther away from the second functional layer with respect to the center of the first functional layer in the thickness direction.

22. The light-emitting element according to claim 20,
wherein the density of the aprotic singlet oxygen scavenger in the first functional layer is higher toward the second functional layer in the thickness direction of the first functional layer.

23-29. (canceled)
